(19) United States
(12) Patent Application Publication
(10) Pub. No.: US 2008/0283110 A1
(43) Pub. Date: Nov. 20, 2008

(54) LARGE SCALE ARRAY OF THERMOELECTRIC DEVICES FOR GENERATION OF ELECTRIC POWER

(75) Inventors: Anjun Jerry Jin, Palo Alto, CA (US); John P. Gotthold, Sunnyvale, CA (US)

Correspondence Address: KOPPEL, PATRICK & HEYBL, 555 ST. CHARLES DRIVE, SUITE 107, THOUSAND OAKS, CA, 91360, US

(73) Assignee: HODA GLOBE COMPANY

(21) Appl. No.: 12/110,097

(22) Filed: Apr. 25, 2008

Related U.S. Application Data
(60) Provisional application No. 60/926,673, filed on Apr. 27, 2007.

(51) Int. Cl. H01L 35/00

(52) U.S. Cl. 136/206

(57) ABSTRACT

A thermoelectric power generating device is assembled from multiple thermoelectric elements disposed in a chip structure, the chip structure forming a power generating core. Multiple cores are stacked within a thermal container such that thermal energy provided at a first end of the thermal container is delivered in a serial manner to the stacked cores. The thermal container includes heat absorbers, heat reflectors and heat transmission barriers so that minimal thermal energy is lost through the walls of the container and maximum thermal energy flows from the heat source through and past the cores to an ambient temperature end of the container so as to create a controlled temperature differential from the hot end to the cooler end of the container as well as across each core stacked therein. The temperature differential across each core results in the generation of electrical energy, such electrical energy being collected by standard power utilization techniques.

This application claims benefit of Provisional Application Ser. No. 60/926,673 filed Apr. 27, 2007.

### FIELD OF THE INVENTION

The present invention relates to the field of power generation using thermoelectric devices, referred to as thermoelectric generators.

### BACKGROUND OF THE INVENTION

The evolution of the production of electrical energy included water wheels or water dam driven turbine electrical generators, steam engine driven electrical generators, internal combustion engine electrical generators, natural gas or steam driven turbine electrical generators, coal fired steam driven turbine electrical generators and atomic power plant steam driven turbine electrical generators. All these prior methods of electricity production caused large environmental disruptions, such as flooding behind dams or air and water pollution from fossil fuel or nuclear fuels.

Recent developments with decreased environmental impact include the solar cell which utilized semiconductor devices to convert solar energy to electricity, originally developed to provide solar power for spacecraft. This technology provided for a thermal to electrical conversion with no moving parts. Some of its limitations are that the conversion efficiency from solar energy to electricity is theoretically limited to twenty nine percent in solar cells based on silicon. As a result of considerable effort the conversion efficiency of the practical solar cell is currently about fifteen percent. Other solar cell conversion technologies such as the use of gallium arsenide and multi-layer junction cells with several layers optimized to absorb different ranges of the solar electromagnetic spectrum, have achieved efficiencies up to forty percent. However, all current solar cells have the limitation that they can only produce power from direct or concentrated, reflected solar rays. No power is produced at night or if there is a lack of sunshine, for example due to seasonal weather conditions.

Attempts to produce lower cost solar cells have resulted in amorphous solar cell substrates. However to date the amorphous substrate solar cells have exhibited a lower photon to electron conversion efficiency than the crystalline variety, typically in the range of six to twelve percent. Other attempts to reduce the cost of production, such as continuous production of thin film solar cells (referred to as roll-to-roll) on thin metallic or plastic substrates, has resulted in a lower conversion efficiency which requires a larger area of solar cells to harvest sufficient sunlight, thus keeping costs high. The best efficiency of solar photovoltaic conversion remains below forty percent and below twenty percent in most practical applications. A great amount of physical material is required to create sufficient area to gather the sun light. The relatively low energy conversion efficiency and the material mass required to produce a significant level of electrical power output has resulted in solar cell based electricity production being a marginal electrical power production technology.

Indirect thermoelectric conversion has been achieved by some other technologies, such as magnetohydrodynamics and ocean thermal energy conversion. In magneto-hydrodynamics a fossil fuel, generally coal, is ionized as it traverses a tube creating a flow of electrical current. In ocean thermal energy conversion, a large structure is created that floats on the ocean. Evaporative thermal fluid is pumped between the warmer ocean surface and the colder ocean depths. This transference turns large turbines attached to generators to produce electricity. These technologies are also limited by low system efficiency.

Another alternative for electrical energy production is based on the wind turbine, one of the oldest energy technologies. Wind mills harnessed the power of the wind by utilizing sails which rotated on a shaft which was geared to turn a stone grinder to grind grain into flour, instead of the traditional method of pounding it by hand with a mortar and pistil. In the early nineteen hundreds wind turbines dotted the landscape. Initially they were mechanical and utilized the winds energy to pump water. With the advent of electrical generators the windmills powered turbines which produced electricity. Examples of current wind turbines include structures which stand three hundred feet tall with one hundred and twenty foot rotating blades driving a turbine to produce five megawatts of electrical output, when the wind is blowing sufficiently. Wind turbine farms generate electricity when the wind blows strong enough to turn the blades, which is on the average about thirty percent of the time.

All of these prior technologies suffered from low conversion efficiency from fuel to electricity, produce environmental pollution, requires large areas (such as dams or wind farms or large solar arrays) or are intermittent (such as solar and wind power).

In contrast, the best technologies for the production of electrical energy should exhibit several features. Primarily, they should be highly efficient in converting an energy source to electricity and they should be non-polluting in construction, use and disposal. They should be scalable from small units with power outputs in watts to larger capacity systems with gigawatt outputs and it should be adaptable to operation in various different environments (i.e., oceans, deserts, arctic poles, or in space) as well as in urban, rural or remote locations.

Heat engines, heat pumps, thermal diodes, thermocouples, and solid-state refrigerators, etc. utilize the thermoelectric (TE) principle in which thermal energy is converted directly to electrical energy.

The Hagelstein and Kucherov U.S. Pat. No. 6,396,191, U.S. Pat. No. 6,489,704 and U.S. Pat. No. 7,109,408 describe the use of thermal diodes, also referred to as solid state thermionic energy converters, to convert thermal energy to electrical energy. Nicoloau U.S. Pat. No. 7,166,796 also disclose n-type and p-type thermoelements for the direct conversion of thermal energy to electrical energy. U.S. Pat. No. 7,273,981 describes systems for the utilization of thermoelectric devices for the production of electricity. The disclosures of these patents and the materials referred to therein are incorporated herein by reference.

### BRIEF DESCRIPTION OF THE DRAWINGS

FIG. 1 is a top view of a portion of an etched substrate for a thermoelectric device incorporating features of the invention.

FIG. 2 is a cross sectional view of the substrate of FIG. 1 taken along line 2-2 of FIG. 1.

FIG. 3 shows the geometry of a typical individual thermoelectric device formed of joined dissimilar materials.

FIG. 4 is a perspective view of a 1 watt power unit including thermal barriers and with the side cutaway to reveal the through channels as shown in FIG. 2.

FIG. 5 is a schematic of a PRU subsection.

FIG. 6 is a cross sectional view of a core assembly comprising three cores enclosed within first, second and third core thermal containers.

FIG. 7 is a schematic diagram illustrating the procedure for forming a multilayer chip including thermoconversion materials.

FIG. 8 shows the core assembly of FIG. 6 mounted in a multi-stacked generator including a heat source.

FIG. 9 is a graphic showing the power output from a single thermoelectric device.

FIG. 10 is a graphic showing the power output from first and second stacked thermoelectric chips in a cool assembly such as shown in FIG. 6.

### DETAILED DISCUSSION

Solar panels use the photovoltaic Laws of Physics. The electrons in the semiconductor materials absorb the photons and in turn generate electricity. However, only a small window of the solar energy (a portion of the spectrum of solar light) is utilized due to the semiconductor energy gap. The photons within this window are converted to electricity at given efficiency. The photons at lower spectrum levels are entirely waste and the photons at the ultra high spectrum level are under utilized. Typical commercial roof top solar panels have an average efficiency of about 15%. Unlike traditional solar panels, devices incorporating features of the invention can utilize heat from the entire light spectrum instead of a converting a portion of the photons delivered and an improved efficiency of conversion of solar light thermal energy to electrical energy results, with a potential efficiency of conversion which can exceed 40%.

However, the invention is not limited to using solar energy as a driving force. Any source of thermal energy, such as concentrated sunlight, combusted fossil fuels, atomically derived heat, waste heat from industrial sites, or environmental temperature differences, can be converted into electricity. Devices incorporating features of the invention, and the methods of using those devices, are optimized to utilize the flow of electrons thermally induced by differential heating of different materials, collectively referred to as the Seebeck effect or Peltier effect. Semiconductor production techniques are used to fabricate an array of selected thermoconversion materials in channels through a substrate and these arrays are assembled in series and parallel arrangement to provide the required electrical output. The array may include two dissimilar metals joined together on one surface of the substrate, the other ends of the dissimilar materials being at a temperature differential from the joint, or the array may be formed using materials which are known to convert heat to an electrical current when the ends there of are exposed to a temperature differential. The array arranged into power-rated units (PRU) with a specified power output per PRU. An array of PRUs is then integrated into a mounting designed to maximize the efficiency of heat utilization from the thermal source by the PRUs and maximize the thermal differential between the thermal source and the opposite end of said devices (i.e., a cooler location). Multiple PRUs are also arranged so that the thermal energy initially provided progresses through the PRUs arranged in series, thus producing additional electricity at each step.

In one embodiment, thermoelectric generators operating in accordance with the invention employ the Seebeck Effect, and operate in accordance with the Thompson Law, to convert heat into electricity in a two or more step process. For example, sunlight is converted into heat by blackbody absorption, and the heat in turn is applied to junctions of dissimilar materials. The opposite ends of the dissimilar materials is at a temperature differential, resulting in the generation of electrical energy. In comparison to the solar cells, the thermoelectric generator, in accordance with the teachings herein, can integrate the solar electric conversion at a system level to significantly increase its efficiency.

In comparison with the majority of currently available thermoelectric devices which are part of thermal signal sensors and generate very low power levels, the invention produces a large power output from a large-scale array of thermoelectric devices. The design of these new thermoelectric devices is optimized by utilizing improved thermal management (minimizing heat loss), proper selection of the materials based on their thermoelectric coefficient, and system specific power circuit design. An embodiment of thermoelectric devices in accordance with the invention utilize the following features:
1) A substrate material electrically isolative as well as resistant to thermal flow, formable in to desired geometric shapes and etchable to allow the formation of passages there through, sometimes referred to as vias, for the formation of thermal device legs is provided. The surface of said substrate material is further etched to form cavities where the thermal device legs can be joined together, creating a dissimilar material interface. A typical material utilized for said substrate material is ceramic.
2) A thermoelectric device comprising two legs, each of a dissimilar material, joined at one end and geometrically optimized to produce electrical current by the Seebeck effect is provided. These dissimilar materials are typically formed in adjacent passages through the substrate material and are connected together in the cavities in one surface of the substrate. The other ends of the legs of the dissimilar materials are also separately connected, at the opposite surface of the substrate, in series, with a third dissimilar material. This third dissimilar material serves as an electrical conduit for recovering the electrical energy resulting from a differential temperatures between the two surfaces of the substrate.
3) A power rated unit (PRU) is formed utilizing a set of multiple thermal electric devices arranged to produce the desired voltage output. A particular embodiment comprises a set of one hundred thermoelectric devices arranged in series to produce one Volt and ten milliamps. Approximately one hundred of said units are then connected in parallel to form an array which produces approximately one Watt.

A set of said PRUs arranged on one contiguous piece of substrate material and formed in a series and parallel connected array of thirty three by thirty three PRUs forms a core capable of producing one kilo Watt of electrical energy. However, the PRUs can be interconnected in a variety of series and parallel arrangement to provide any desired Voltage and Amperage combination that is desired.

In one embodiment, a thermoelectric generator comprises three cores arranged and thermally packaged so that thermal energy lost is minimized and the utilization of the temperature differential is maximized. A first core is exposed to a thermal energy differential to generate electrical energy. That thermal energy is then directed to and utilized by the second core and then the third core. Utilizing stacked cores a thermal energy to electrical conversion efficiency between forty and eighty percent can be achieved, depending on the thermal containment efficiency of the materials utilized to redistribute the thermal energy. Such an arrangement typically produces in excess of one kilowatt of electrical power.

A thermal generator incorporating the features described herein arranged in proximity to a suitable thermal heat source with multiple stacked and interconnected series and parallel connected thermoelectric generators can produce electrical output in the multi-kilo watt, megawatt or even gigawatt electrical power ranges.

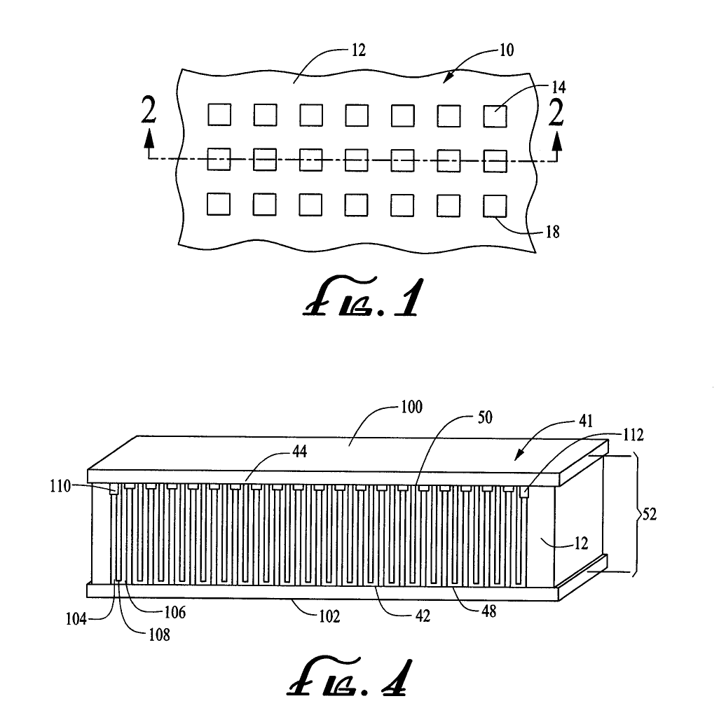

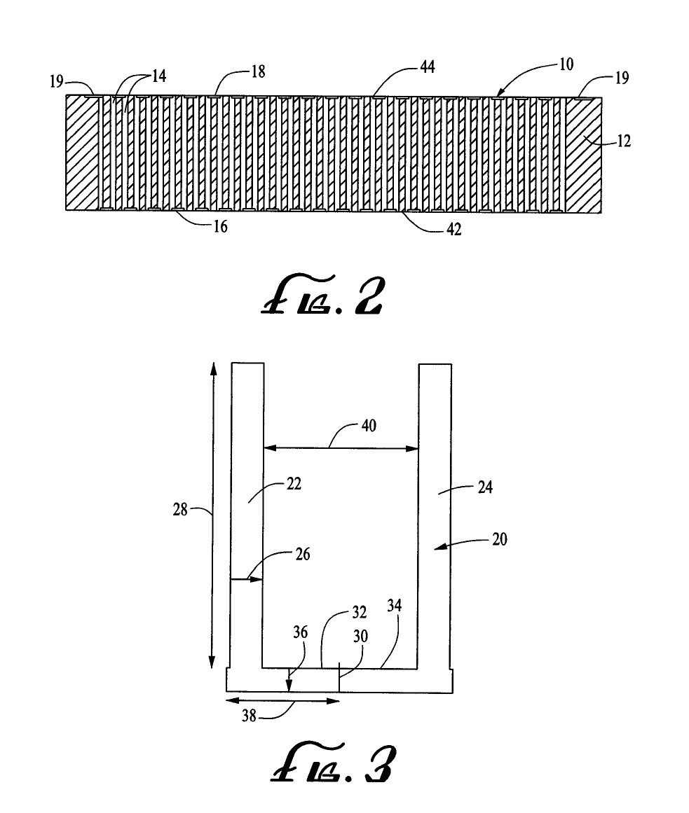

Referring to FIGS. 1 and 2, a first embodiment of a thermoelectric device chip 10 is shown. FIG. 1 is a top view and FIG. 2 is a cross sectional view of a substrate material 12 with through passages, vias or channels 14 etched therethrough using semiconductor processing techniques. The substrate is a material of minimal thermally conductive such as silicon or a ceramic material. Thermoelectric device junction cavities 16 and thermoelectric device leg interconnects cavities 18 are etched into opposite surfaces of said substrate material 12. Interconnection pad cavities 19 are also etched into the substrate material on the interconnect side at the opposite ends of the substrate 12.

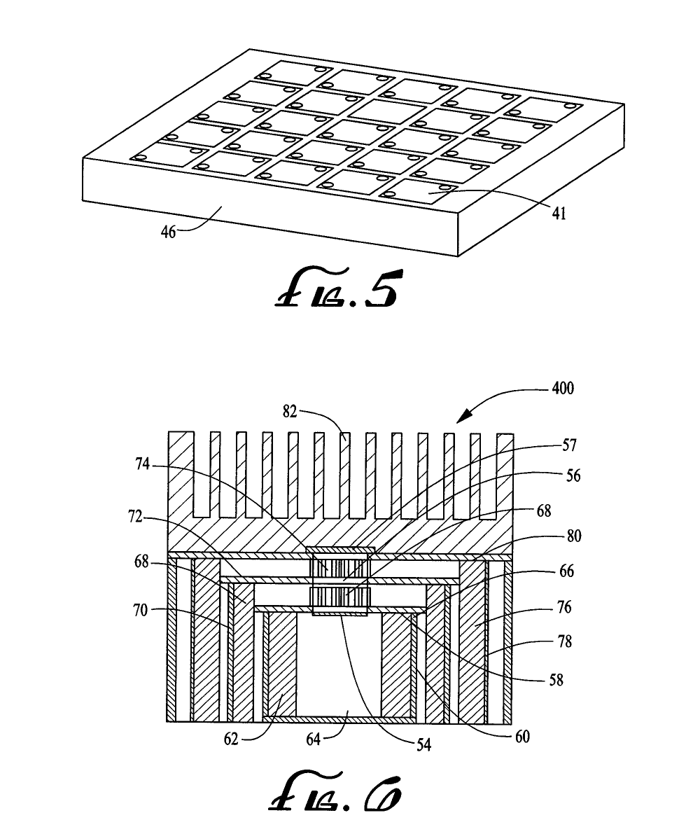

FIG. 3 shows the geometry of a typical individual thermoelectric (TE) device 20 which is deposited in the channels 14 and cavities 16, 18. The TE device 20 comprises first and second legs 22, 24 of dissimilar materials which are formed in the passages 14 in the substrate 12. The legs 22, 24 have a cross section 26 of from about 0.25 to about 50 micron and a length 28 of 50 to 700 micron with a cross section 26 to length 28 ratio in the range of from about 1:3 to about 1:20.

The first and second legs 22, 24, formed of dissimilar materials, each have a foot 32, 34 which are interfaced (fused or joined) at a junction 30 with a ratio of leg cross section 26 to foot cross section 36 of from about 0.5:1 to about 2:1. The length of the foot extension 38 of said TE device leg is about 2 to about 5 times the width of the leg cross section 26. As a result, the distance between the legs 40 is from about 2 to about 8 times the width of the leg cross section 26. Examples of suitable combinations of dissimilar materials that can be used to construct the TE device shown in FIG. 3 include, but are not limited to, Constantan:Chromel, Chromel:Copper, Iron:Constantan, Copper:Constantan, Chromel:Alumel. In the thermal conversion devices and structures described herein, thermal energy is delivered to the side of the substrate where the junction is formed (i.e., the foot), generally referred to as the hot or relatively hotter surface. The opposite surface of the substrate where the top of the legs exit is referred to as the cool or relatively cooler surface. At a temperature differential of about 80° C., a typical output per junction of such a device formed from Constantan:Chromel is approximately 5 mV. However, one skilled in the art will recognize that the junction can be the cooler surface, for example a temperature less then ambient with the other surface at a higher temperature, for example ambient, and the dissimilar metals will still generate an electrical output.

In an alternative embodiment, materials which are known to have thermoelectric properties, namely convert heat directly into electricity can also be used. These include, but are not limited to (BiSb)₂Te₃, Zn₄Sb₃, CeFe₄Sb₁₂, PbTe, SnTe, SiGe, Bi₂Te₃, Sb₂Te₃, Skutterudites (Skutterudites are complex materials whose chemical formula is ReTm₄Pn₁₂ where Re is a rare earth material such as cerium, Tm a transition metal, for instance, iron, and Pn are pnictides, (i.e., phosphor, arsenic, or antimony) and TAGS (a Te/Ag/Ge/Sb alloy). In such an instance it is not necessary to create a junction of dissimilar materials to convert thermal energy to electrical energy as electrical energy is generated by exposing a structure formed from these materials to a temperature differential.

One skilled in the art will recognize that the TE device can be formed from numerous other materials which are listed in handbooks for constructing thermocouples and that new alloys or combinations of thermoelectrically active materials continue to be discovered that can be exposed to heat, a heat differential and/or light to generate an electrical output.

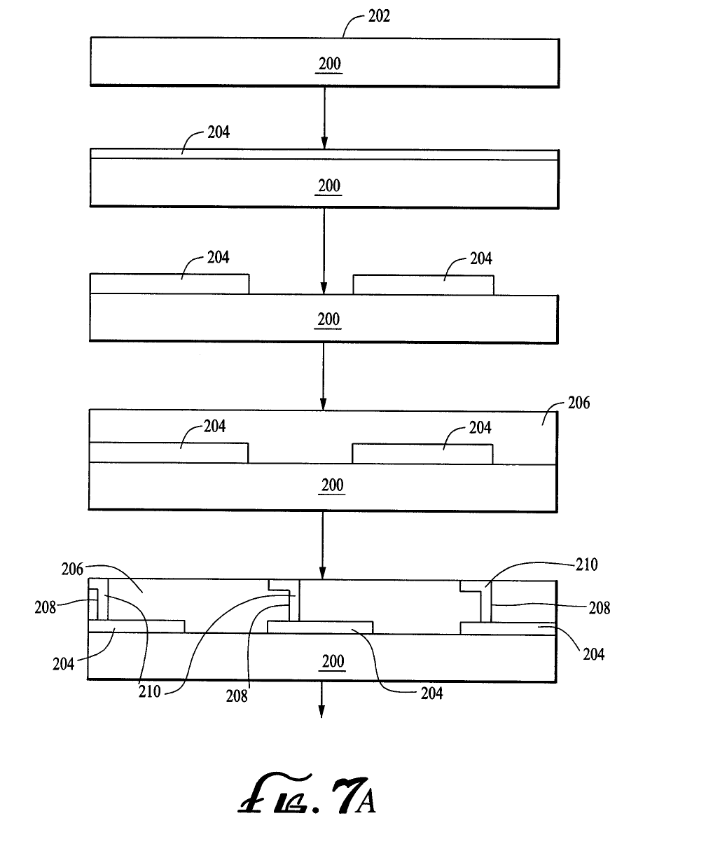

FIG. 4 is a perspective view of a 1 watt power rating unit (PRU) 41. The junction surface 42 of the substrate 12 is covered with a layer or layers of a thermally reflective material, such as aluminum, while avoiding making electrical connection with the feet 34 or junctions 30. The surface opposite the junctions, namely the cooler surface 44 with the tops of the legs exposed is provided with interconnects between the tops of the legs of an electrically conductive material, such as copper, in a serial and parallel pattern to create the desired series voltage and parallel amperage outputs. A typical sub-array has two hundred sets of thermoelectric devices 10 serially connected to produce approximately one volt. Approximately two hundred of these sub-arrays of the series sets are then connected in parallel to produce a PRU 41 with a one amp output, the result being a one Watt power rating unit (PRU).

Referring to FIG. 4, ceramic caps 100, 102 are placed on the cold surface and hot surfaces to provide thermal insulation and maintain a temperature differential between the ends of the thermoelectric devices within the PRU. A first thermoelectric material 104 and a second thermoelectric material 106 located in adjacent channels 14 are joined at the bottom of the channels forming a biometallic joint 108. In a first embodiment the first and second thermoelectric materials are metals typically used to form thermocouples, referred to as non-noble alloy materials, such as constantan:chromel, Chromel:Copper, Iron:Constantan, Copper:Constantan, Chromel:Alumel, or tungsten-rhenium based. The Seebeck coefficients at 0° C. (32° F.) for representative materials are −72.0 for Bismuth, 47.0 for Antimony, 500.0 for Tellurium, 300 for Germanium and 400 for Silicon.

In second embodiment, they are materials which, when exposed to temperature differentials provide electrical current. A material with a positive thermal electric coefficient (N-type) is paired with a material with a negative thermal electric coefficient (P-type). For example various TE materials may be produced in P-type or N-type materials by varying doping materials and/or stoichiometry. The semiconductor manufacturing process described herein have been used to assemble P-type and N-type Bi₂Te3 thermoelectric elements. These elements can be used to form a high efficiency thermoelectric generator. For example, the Seebeck coefficient of N-type bismuth telluride is −287 μV/K; the Seebeck coefficient of P-type Bismuth Telluride is 81 μV/K.

As indicated above these thermoelectric devices are appropriately connected in series and parallel to electrical conductors, such as copper conductors, on the cold side 44 so that the electrical current generated can be collected, the conductors terminating at a positive bus bar 110 and a negative bus bar 112. Appropriate electrical conductors then connect the bus bars on multiple PRUs to deliver the electrical energy to provide a total system output.

FIG. 5 is a schematic of a PRU sub-section 46 which comprises twenty-five (a 5 by 5 array) of PRUs 41, each providing one Watt, formed on the surface of a substrate material. A typical power unit may comprise 1000 of these one Watt PRU sub-sections 46 interconnected in series and parallel configuration to produce one kilowatt of electrical power at any desired amperage and voltage. The PRU sub-section 46 comprises a thermally conductive but not electrically conductive thin layer film that is typically 50 micron to 200 micron thick grown and contain etched-through holes that are typically formed via semiconductor processing techniques.

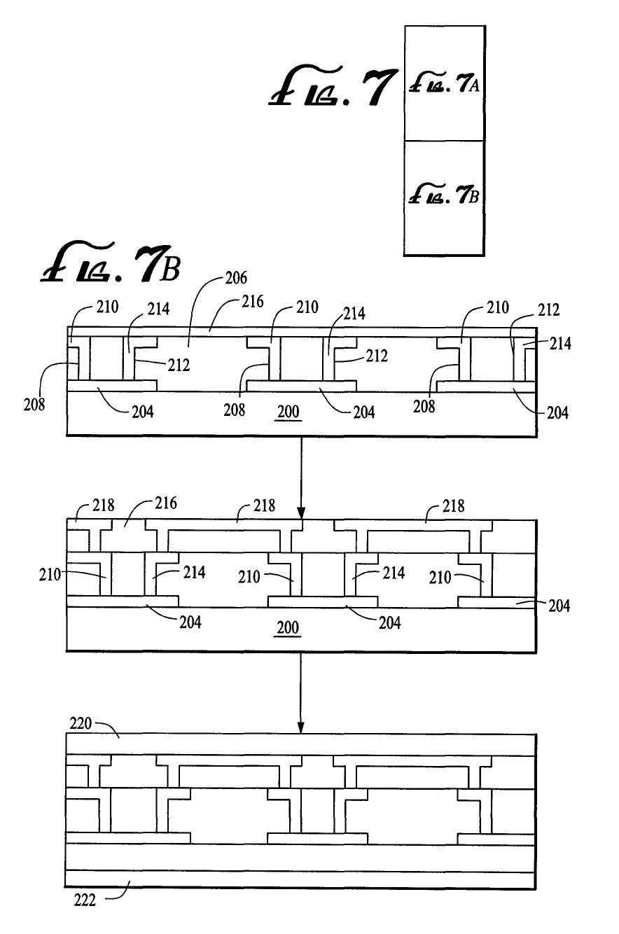

FIG. 6 is a cross-sectional view of an embodiment of a structure incorporating features of the invention along with features for thermal management. A PRU 41 such as shown in FIG. 4 is covered by a layer of a thermally conductive material 48, such as Aluminum Nitride. This layer also protects the thermoelectric devices 10 from environmental damage and acts as a black body thermal energy absorber. The opposite, relatively cooling surface of the substrate material with included thermoelectric devices is also coated with a thermally conductive protective layer 50, such as Aluminum Nitride, which transmits the thermal energy migrating from the relatively hotter surface through the legs 22, 24 of the thermoelectric device to the relatively cooling surface. Integrated into the protective layers 48, 50 are passages (not shown) for thermocouples 52 to allow an accurate measurement of the temperature differential of the two protective layers. Passages (not shown) are also formed through the protective layer 48, 50 and the ceramic caps 100, 102 to provide conduits for the conductors attached to the positive and negative buses 110, 112 for collecting the electricity created in the thermoelectric device. While the device of FIG. 5 is shown as a rectangular structure, the thermal generator can be any geometric shape. In addition, the protective layer on the relatively hotter side can be supplement by the addition of materials or structure to enhance the thermal uptake of the protective cover and the protective cover on the relatively cooler side may be supplement by the addition of materials or structure to enhance thermal dissipation so as to maintain as high a differential temperature as possible between the thermal side (the hotter side) and the non thermal side (the cooler side).

Multiple stacked cores can be arranged in a single structure 400 to achieve maximum thermoelectric conversion efficiency. FIG. 6 shows three stacked cores. In a preferred embodiment, the output efficiency of the thermoelectric power unit is increased by applying thermal energy input to multiple conversion units. The multiple cores are arranged such that the excess thermal input applied to the first core is transferred to the second and then to the third core in a controlled manner. FIG. 6 shows first, second and third stacked conversion cores 54, 56, 57. The first core 54 is mounted in a thermally isolative housing 58 composed of a thermally resistive material, preferably a ceramic material. This isolative housing 58 is thermally isolated by a reflective thermal barrier 60 composed of layers of aluminum or other thermally reflective materials. Inwardly from the reflective thermal barrier 60 is a heat absorbing material 62 which, in combination, serves to contain input thermal energy which enters by way of passage 64 or other thermal transmissive or delivery means. The thermal energy that enters passage 64 is absorbed by the heat absorbing material 62 which maintains a constant temperature in the area of the first core 54. The reflective thermal barrier 60 reflects the thermal energy contained in the heat absorbing material 62, keeping it from escaping from the thermal input side of the first core 54.

Thermal energy reaching the thermal input side of the first core 54 causes electrical energy to be generated by the thermoelectrical devices within the core. That electrical energy is recovered through conductive leads (not shown in FIG. 6) attached to the core and exiting from the assembly. The combination of the first conversion cores 54, thermally isolative housing 58, thermal barrier 60, heat absorbing material 62 and passage 64 is referred to as the first core thermal container 66.

The thermal energy that escapes from the top (the relatively cooler surface) of the first core 54 in the first thermal container 66 is transmitted by a thermal throttle 68, composed of a thermally conductive and electrically isolative material, mounted between the relatively cooler side of the first core and the hot side of the second core 56. That transmitted thermal energy is utilized by the second core 56 to generate additional electrical energy from the thermal energy passing through and utilized by the first core 54. There may also be some thermal energy that bypasses the first and is directed to the hot side of the second core 56.

The second core 56 is also thermally enclosed within a similar thermal barrier contained by materials comprising a second heat absorbing material 68, a second reflective barrier material 70 and a second thermally isolative housing 72 which are selected and sized to maintain a thermal steady state condition of the first core thermal container 66. In a like manner, the thermal energy passing through the cooler surface of the second core 56 is transmitted by a second thermal throttle 74 to the third core 57 which, in the same manner is isolated by third heat absorbing material 76, a third reflective barrier material 78 and a third thermally isolative housing 80. The three stacked cores are arranged such that the thermal energy utilized by the first core 54, the second core 56 and the third core 57 exits through the cold side of the third core 57 through a thermal dissipative means 82, which is preferably at ambient temperature, thus maintaining a uniform thermal flow through all three of the stacked cores 54, 56, 57. Because the thermal to electric conversion created in each core utilizes a portion of the initial thermal energy, the thermal to electric efficiency of the stacked, thermally isolated cores is in the range of 40% to 80%, depending on the thermal differential and thermal retaining capability of the barrier materials. Under preferred operating conditions the temperature differential from the hottest point in the first core thermal container 66 to the exterior surface of the thermal dissipative means 82 is from about 50° C. to about 300° C. and most preferably from about 70° C. to about 80° C.

Multiple stacked cores can be arranged in any configuration that effectively utilizes said input thermal energy. While FIG. 6 shows three stacked cores, based on the teachings herein one skilled in the art will recognize, for example, that additional cores can be stacked and that multiple cores can be placed within the various thermal containers formed by the combinations of absorbing materials, reflective barrier materials, and thermally isolative housings.

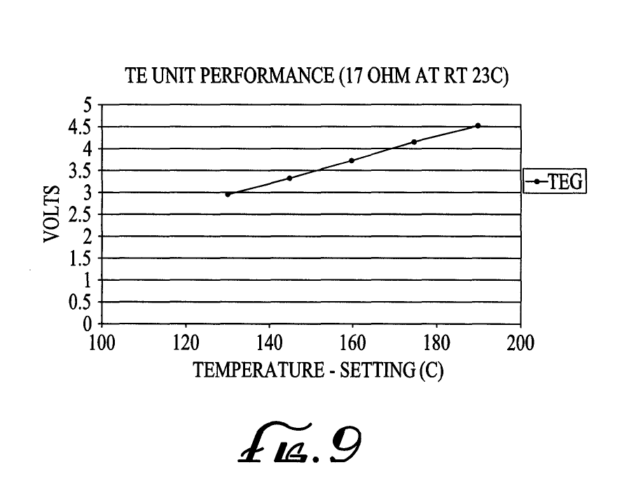

FIG. 8 shows the multiple stacked structure 400 of FIG. 6 mounted on top of heat source. For example, if the heat source is a combustion chamber the assembly operates as a portable electrical generator. This structure can be stove-top mounted. The top stacks generate high efficiency TE power mounted on the hot-side with large thermal mass.

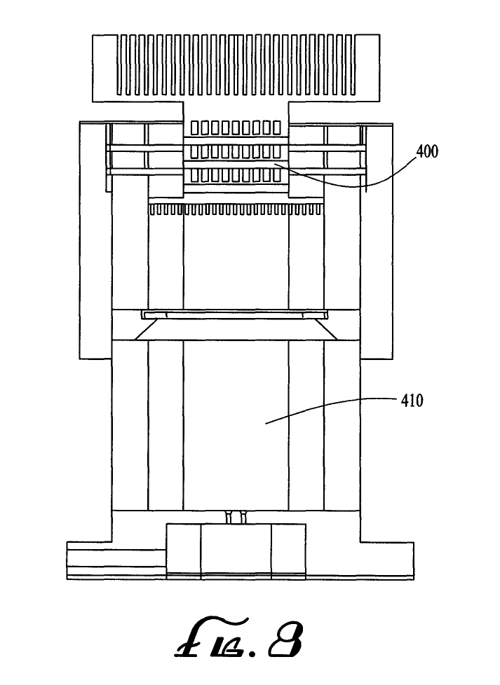

FIG. 7 illustrates an alternative method of fabricating one or more thermoelectric devices on a substrate. A substrate 200 preferably about 1000 um thick is prepared with at least one polished surface 202. The substrate is not electrically conductive and is preferably a good thermal conductor such as silicon. An electrically conductive film 204 such as an aluminum coating is applied to the polished surface and masked and etched in a desired pattern. This film 204 will serve to form the junction between subsequently deposited thermoelectric materials. A low-k electrically non-conductive insulation 206 is then applied over the etched conductor 204 and first channels 208 are formed therein, such as by lithography and etching, followed by deposition of a first thermoelectric generating material 210 in those first channels. An example of a suitable low-k insulation 206 is a combination of an insulating polymer and Mylar® in a layered arrangement with about 100-200 layers/mm. An example of a first thermoelectric generating material 210 is tungsten.

The upper surface is then masked and similar techniques are used to form a second set of channels 212, followed by deposition of a second thermoelectric generating material 214, such as chromel, in those second channels 212. A suitable low-k insulation 216 is then applied and it is etched to provide channels for placement of a second electrically conductive material 218, such as another aluminum conductor, to connect the appropriate cooler ends of the first and second thermoelectric generating materials 212, 214. High-k ceramic covers 220, 222 are then applied to the top and bottom of the device.

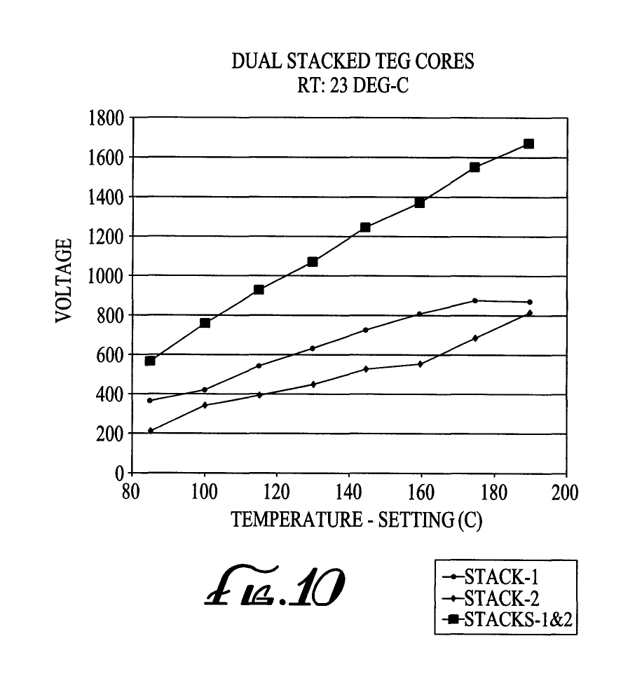

FIG. 9 is a graph showing the power output of a thermoelectric device in accordance with the teachings herein composed of Bi₂Te₃ operating at a temperature differential of from about 120° C. to about 190° C.

FIG. 10 is a graph showing the power output of multiple thermogenerator devices in a core (approximately 500 devices/core) with two cores stacked in a structure such as shown in FIG. 6. Operating at a temperature differential of from about 80° C. to about 190° C. each of the first and second cores generates from about 200 to about 800 volts. Because these cores are stacked within the same thermal container, the total power output from the two cores which contain in total about 1000 thermogenerating devices is from about 800 to about 1700 volts.

The thermal electrical energy conversion devices described herein can be powered by any thermal source, such as concentrated sunlight, fossil fuel combustion, heat generated by nuclear reactors, waste heat from industrial processing equipment, factories or exhaust stacks, motor vehicle exhausts, geothermal heat or any other thermal source to generate electricity from the heat lost through system inefficiency, such as engine exhaust, heat exchangers, etc.

Preferably, the temperature of the thermal source is above ambient temperature. However, the basic requirement of the thermoelectric generators described herein is that there exists a temperature differential. Accordingly, the temperature differential could be provided by a source with a temperature less then ambient. As an example, the thermoelectric generators could be operated with the hot side being ambient and the cool side being within a refrigerated zone such as a refrigerator or freezer used for food storage or a cooler stream or bed of water surrounded by a warmer ambient environment.

The thermoelectric generator assemblies described herein can be utilized to produce electrical power in a hybrid mode by using a variety of stored thermal energy producing fuels such as, methane, propane, butane, geothermal, and hydrogen, etc., in stand alone mode or to augment other thermal energy systems such as solar heat, geo-thermal energy or atomic generated thermal energy. Multiple generators can also be multiplexed into large arrays to produce electrical power in the multi kilowatt, megawatt and even gigawatt range.

The generators can be used in stationary power generation systems or assembled as portable and/or the tabletop devices to produce electrical power supply for residential and small business applications. The invention can also be applied to mobile devices such as for use by military personnel on remote missions, for space exploration applications, and on commercial and personal automotive vehicles.

1. A thermoelectric power generating system comprising multiple thermoelectric devices assembled to form power generating units and multiple power generating units connected by heat transferring device there between and arranged within one or more thermal containment units, said thermal containment units constructed to receive thermal energy from an elevated temperature source at one end thereof, transfer that thermal energy to an opposite end of the one or more thermal containment units, said opposite end being at a lower temperature such that a temperature differential is created between the first end and the second end, the thermal energy being delivered to the thermoelectric devices enclosed within the thermal containment units,
the thermoelectric devices comprising a plurality of discrete thermoelectric elements disposed in and extending through an electrically non-conductive substrate to form the power generating units, the power generating units positioned within the thermal containment units such that a first end of each thermoelectric element is located at a relatively higher temperature and a second end of each thermoelectric element is located at a relatively lower temperature along the temperature gradient, said second ends being connected to electrical conduits configured to collect electrical energy generated by the thermoelectric elements as a result of said temperature differential,
the electrical output from said multiple thermoelectric devices being connected in a series or parallel configuration, or a series and parallel configuration within the thermoelectric power generation units,
the heat confining structure including multiple layered heat absorbing materials and heat reflecting materials arranged as thermally isolative housings optimized to deliver the thermal energy to the multiple thermoelectric power generation units stacked in an ascending order in the heat confining structure.

2. The thermoelectric power generating system of claim 1 wherein the thermoelectric elements comprise pairs of dissimilar materials extending through the electrically non-conductive substrate a first end of each being joined together to form a joint and second ends thereof spaced from the joint, said joint located at a position closer to the elevated temperature source than the second ends.

3. The thermoelectric power generating system of claim 2 wherein the dissimilar materials of thermoelectric elements comprise pairs of materials suitable for forming a thermocouple.

4. The thermoelectric power generating system of claim 3 wherein the paired materials are selected from Constantan:Chromel, Chromel:Copper, Iron:Constantan, Copper:Constantan, Chromel:Alumel.

5. The thermoelectric power generating system of claim 3 wherein the thermoelectric elements are selected from the groups consisting of Bi₂Te₃, (BiSb)₂Te₃, Zn₄Sb₃, CeFe₄Sb₁₂, PbTe, SnTe, SiGe, Bi₂Te₃, Sb₂Te₃, Skutterudites and Te/Ag/Ge/Sb alloys.

6. A power generating unit comprising multiple thermoelectric generating chips, said chips generating electric current upon exposure to a differential temperature, each chip comprising:
a heat conductive, electrically non-conductive substrate, said substrate having a heat receiving surface and a interface surface spaced from the heat receiving surface,
an insulator comprising a low-k, electrically non-conductive material formed on the interface surface, said insulator material having a junction surface at the interface surface and a second surface spaced therefrom,
said insulator having multiple channels extending therethrough from the second surface to the junction surface, said multiple channels enclosing thermoelectric materials, said thermoelectric materials having a junction end at the junction surface and an electric current delivery end at the second surface, multiple current delivery ends connected in series or in parallel with like electric current delivery ends connected to each other by electrically conductive conduits to provide a power output from said chip,
the chip further including high-k electrically non-conductive covers over the heat receiving surface and the second surface to form a power generating core.

7. The power generating unit of claim 6 wherein the thermoelectric materials located in pairs of adjacent channels are joined at the interface surface, each of the two electric current delivery ends of the pairs being connected on the second surface to conduits to provide power output from the chip.

8. The power generating unit of claim 6 wherein multiple power generating cores are assembled in a stacked arrangement, each core having a heat receiving surface and a relatively cooler heat delivery surface, the heat receiving surface of the first of the stacked cores being exposed to an elevated temperature heat source and the heat delivery surface of the upper most of the stacked cores being exposed to a relatively cooler temperature such that each of the stacked cores is exposed to a temperature differential with the heat delivery surface of each core transmitting heat to the heat receiving surface of the adjacent core stacked thereon.

9. The power generating unit of claim 6 wherein the thermoelectric materials comprise pairs of similar or dissimilar materials extending through the electrically non-conductive insulator, a first end of each being joined together to form a joint and second ends thereof spaced from the joint, said joint located at a position closer to the elevated temperature source than the second ends.

10. The power generating unit of claim 9 wherein the dissimilar materials comprise pairs of materials suitable for forming a thermocouple.

11. The power generating unit of claim 9 wherein the paired materials are selected from Constantan:Chromel, Chromel:Copper, Iron:Constantan, Copper:Constantan, Chromel:Alumel.

12. The power generating unit of claim 9 wherein the thermoelectric materials are selected from the group consisting of Bi₂Te₃, (BiSb)₂Te₃, Zn₄Sb₃, CeFe₄Sb₁₂, PbTe, SnTe, SiGe, Bi₂Te₃, Sb₂Te₃, Skutterudites and Te/Ag/Ge/Sb alloys.

13. The power generating unit of claim 8 wherein the temperature differential between the heat receiving surface of the first of the stacked cores and the relatively cooler heat delivery surface of an upper most core is from about 80° C. to about 190° C.
